(19) United States
(12) Patent Application Publication
(10) Pub. No.: US 2009/0238382 A1
(43) Pub. Date: Sep. 24, 2009

(54) AUDIO REPRODUCTION SYSTEM

(75) Inventors: Naoki UNOU, Gifu-shi (JP); Kazuhiko KONDO, Ogaki-shi (JP)

Correspondence Address: CANTOR COLBURN, LLP, 20 Church Street, 22nd Floor, Hartford, CT, 06103, US

(73) Assignees: SANYO ELECTRIC CO., LTD., Osaka (JP); SANYO SEMICONDUCTOR CO., LTD., Gunma (JP)

(21) Appl. No.: 12/407,315

(22) Filed: Mar. 19, 2009

(30) Foreign Application Priority Data
Mar. 19, 2008 (JP) JP2008-070612

(51) Int. Cl. H03F 99/00; G06F 17/00

(52) U.S. Cl. 381/120; 700/94

(57) ABSTRACT

The audio reproduction system amplifies and reproduces both a digital audio signal and an analog audio signal. After delta sigma modulation by a ΔΣ modulator, the digital audio signal is pulse width modulated by a first PWM converter and supplied to a selector. The analog audio signal is compared with a PWM carrier signal by a second PWM converter, converted to a PWM signal, and supplied to the selector. A signal selected by the selector is then amplified by a class D amplifier.

### CROSS-REFERENCE TO RELATED APPLICATION

The disclosure of Japanese Patent Application No. 2008-070612 filed on Mar. 19, 2008, including specification, claims, drawings, and abstract, is incorporated herein by reference in its entirety.

### BACKGROUND OF THE INVENTION

1. Field of the Invention

The present invention relates to an audio reproduction system for amplifying and reproducing both digital and analog audio signals.

2. Description of the Related Art

Heretofore, the two types of audio signal reproduction include the reproduction of digital signals, such as from CDs and DVDs, and the reproduction of analog signals, such as from AM and FM radio. Therefore, in audio reproduction systems, it is necessary to have the capability of reproduction for inputs for both digital and analog. For digital audio signals in this type of system, particularly in portable devices, PWM signals are often amplified by a class D amplifier after delta sigma (ΔΣ) modulation. The reason for this is class D amplifiers have good power efficiency and it is desirable for the audio reproduction system to have the lowest possible power consumption in portable devices where battery life becomes a problem. Thus, after ΔΣ modulation by a ΔΣ modulator, digital audio signals obtained from playback of a CD or DVD are converted to PWM signals, and then amplified by a class D amplifier. On the other hand, for analog audio signals, the signals are amplified by a class AB amplifier.

Furthermore, Japanese Patent Laid-Open Publication No. 2006-333437 (referred to hereinafter as Patent Document 1) discloses a configuration for converting an analog audio signal to a digital signal with an ADC circuit and supplying this digital signal to a class D amplifier via a PWM converter, which performs PWM conversion for digital audio signals. According to this configuration, the class AB amplifier can be omitted.

### SUMMARY OF THE INVENTION

However, in the circuit of Patent Document 1, a digital signal obtained by A/D conversion from an analog audio signal and a digital audio signal are supplied to a single PWM converter. The digital audio signal is generally a digital signal that has undergone PCM conversion. Therefore, to obtain such a digital signal, after ΔΣ modulation, it is necessary to process the analog audio signal with a digital filter. Consequently, a combination of a ΔΣ modulator and a digital filter becomes necessary in the ADC circuit resulting in a problem where the circuit configuration becomes comparatively large.

The present invention is an audio reproduction system for amplifying and reproducing both a digital audio signal and an analog audio signal and includes a delta sigma modulator for performing delta sigma modulation on the digital audio signal, a first PWM converter for converting an output of the delta sigma modulator into a PWM signal by pulse width modulation, a second PWM converter for comparing the analog audio signal and a PWM carrier signal and converting into a PWM signal, a selector for selecting and outputting either output of the first PWM converter or the second PWM converter, and a class D amplifier for receiving and amplifying the output of the selector.

### BRIEF DESCRIPTION OF THE DRAWINGS

FIG. 1 is a block diagram showing a configuration of an embodiment.

### DETAILED DESCRIPTION OF THE PREFERRED EMBODIMENTS

The embodiment of the present invention will be described with reference to the attached drawing.

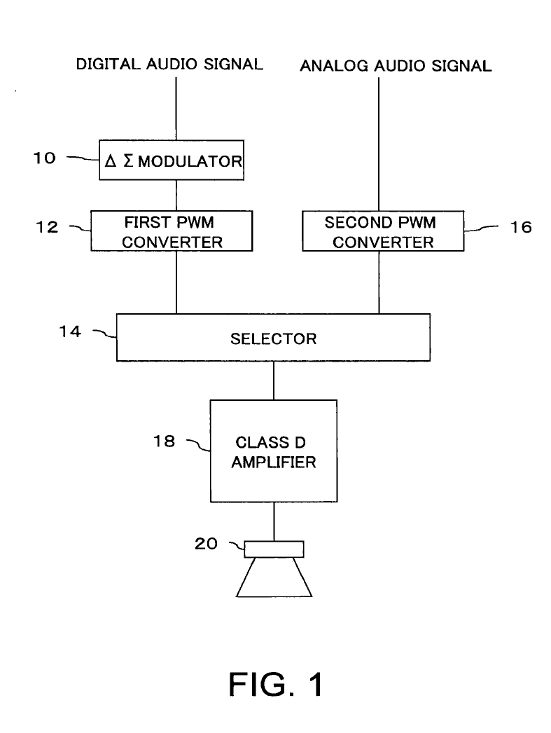

FIG. 1 is a block diagram showing a configuration of an embodiment. A reproduction apparatus of the embodiment performs amplification of both a reproduced digital audio signal, such as that obtained from a CD or DVD, and a reproduced analog audio signal, such as that obtained from FM radio. Reproduction of both signals cannot be performed simultaneously and one is selected so that either the digital audio signal or the analog audio signal is input.

For example, a 44.1 kHz, 16-bit digital audio signal obtained from the reproduction of a CD is input by a delta sigma (ΔΣ) modulator 10. The ΔΣ modulator 10 performs delta sigma (ΔΣ) modulation on the input digital audio signal for conversion to a one-bit or multi-bit signal at a higher predetermined frequency.

Then, this one-bit or multi-bit signal is converted to a PWM signal at a first PWM converter 12. Namely, the PWM signal is generated with a duty determined according to a value of the one-bit or multi-bit signal at a frequency of the PWM carrier signal. The PWM signal is then supplied to a selector 14.

Furthermore, the analog audio signal, such as from a radio tuner, is supplied to a second PWM converter 16 where it is directly compared with a PWM carrier signal, such as a triangular wave, so as to yield a PWM signal with a duty ratio determined according to the comparison result showing which of the PWM carrier signal or the analog audio signal is larger. The PWM signal is then supplied to the selector 14.

The input of either the digital audio signal or the analog audio signal is determined by a selection signal, such as from a microprocessor for controlling the overall audio set. Consequently, the selection signal controls the selector 14 so that the signal to be input is selected.

It is preferable to use the selection signal to terminate the power supply to either the combination of the ΔΣ modulator 10 and the first PWM converter 12 or the second PWM converter 16, whichever is unused. 5 The PWM signal that was selected by the selector 14 is supplied to a class D amplifier 18 where the signal is amplified, converted to an analog signal, and then output. The analog signal is then supplied to a speaker 20 from which sound is output according to the signal so that the input signal is reproduced.

In this manner, according to the embodiment, either the digital audio signal or the analog audio signal is amplified by the single class D amplifier 18. Therefore, the power efficiency increases and the power consumption can also be controlled to a low level. Furthermore, a circuit such as the embodiment is generally formed from an integrated circuit (IC) and the surface area of the IC and the number of components can be reduced. For the digital audio signal, the combination of the ΔΣ modulator 10 and the first PWM converter 12 is generally employed to yield the PWM signal. For the analog audio signal, the signal is directly converted to the PWM signal at the second PWM converter 16. Therefore, an A/D converter including a ΔΣ converter and a digital filter as shown in Patent Document 1 is not required and the overall circuit size can be made smaller.

While there has been described what are at present considered to be preferred embodiments of the invention, it will be understood that various modifications may be made thereto, and it is intended that the appended claims cover all such modifications as fall within the true spirit and scope of the invention.

What is claimed is:

1. An audio reproduction system for amplifying and reproducing both a digital audio signal and an analog audio signal, comprising:
a delta sigma modulator for performing delta sigma modulation on the digital audio signal;
a first PWM converter for converting an output of the delta sigma modulator into a PWM signal by pulse width modulation;
a second PWM converter for comparing the analog audio signal and a PWM carrier signal and converting to a PWM signal;
a selector for selecting and outputting either output of said first PWM converter or said second PWM converter; and
a class D amplifier for receiving and amplifying the output from said selector.

2. A system according to claim 1, wherein:
said selector selects either output of said first PWM converter or said second PWM converter in accordance with a control signal from an external source.

3. A system according to claim 1, wherein:
said first PWM converter determines the duty ratio of said PWM signal in accordance with a value of the output of said delta sigma modulator.
